(19) United States
(12) Patent Application Publication
(10) Pub. No.: US 2007/0023868 A1
(43) Pub. Date: Feb. 1, 2007

(54) Method of forming copper metal line and semiconductor device including the same

(75) Inventor: Hong Ji Ho, Hwaseong-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU ELECTRONICS CO., LTD.

(21) Appl. No.: 11/494,643

(22) Filed: Jul. 28, 2006

(30) Foreign Application Priority Data
Jul. 28, 2005 (KR) 10-2005-0068737

(51) Int. Cl. H01L 29/40; H01K 3/10

(52) U.S. Cl. 257/621; 29/852; 29/847

(57) ABSTRACT

A semiconductor device includes a substrate having a bottom metal line formed therein; a nitride layer and an oxide layer having a trench and a via hole, the via hole exposing the bottom metal line; a barrier metal layer formed inside the trench and the via hole; a seed layer formed on the barrier metal layer inside the trench and the via hole; and a copper line formed on the seed layer inside the trench and the via hole.

### RELATED APPLICATION

This application is based upon and claims the benefit of priority to Korean Application No. 10-2005-0068737, filed on Jul. 28, 2005, the entire contents of which are incorporated herein by reference.

### BACKGROUND

1. Technical Field

The present invention relates to a semiconductor device manufacturing technology, and more particularly, to a method of forming a copper metal line of a semiconductor device, and a semiconductor device including the same.

2 Description of the Related Art

With the down-scaling of semiconductor devices, the speed and degree of integration of semiconductor circuits constantly increase. However, when semiconductor devices are scaled down, connection lines are also scaled down, resulting in increased line delays, which prevents further improvement of the speed of the semiconductor circuits.

One potential resolution to the problem of increased line delay is to use copper together with an aluminum alloy in forming the connection lines, because copper has a low electrical resistance and a high electro-migration (EM) resistance, and aluminum alloy is suitable for large scale integration (LSI).

Because copper is not easily etched and because it oxidizes, copper lines are generally formed with a damascene process. In the damascene process, an insulation layer is formed on a structure to which a connection is to be formed. Then, trenches and/or vias are formed in the insulation layer. Copper is then filled in the trenches and/or vias and planarized by a chemical mechanical polishing (CMP) process to form trench lines in the trenches and/or via plugs in the vias. The damascene process may be a single damascene process in which the via plugs and the trench lines are separately formed, or a dual damascene process in which the via plugs and the trench lines are simultaneously formed.

The copper may be filled in the trench and/or the via using an electroplating method, which forms a copper layer using an electrolyte containing a copper solute and an acid solvent.

A copper metal line using the electroplating method is formed as follows. First, an insulation layer is formed on a substrate, and via holes and trenches are formed in the insulation layer. Then, a barrier metal layer is formed on the sidewalls and the bottom of the via holes and the trenches. In a 0.13 μm copper damascene line process, the barrier metal layer may comprise a Ta-based metal, such as TaN/Ta. Next, a copper seed layer is formed on the barrier metal layer for electroplating. A copper layer filling the via hole and the trench is formed on the seed layer through electroplating. The copper layer is polished to form copper metal lines and via plugs using a CMP process until the insulation layer is exposed.

Because copper metal lines are formed with a 0.13 μm line process and aluminum alloys are formed with a 0.18 μm line process, both the 0.13 μm copper metal line process and he 0.18 μm aluminum line process need to be performed. Moreover, the barrier metal layer comprising a Ta-based metal is generally formed using a chemical vapor deposition (CVD) method, where a Ta target for CVD is very expensive. Furthermore, the seed copper layer, if exposed to air, quickly oxidizes.

### SUMMARY

Embodiments consistent with the present invention provide a method of forming a copper metal line and a semiconductor including the same that substantially obviate one or more problems due to limitations and disadvantages of the related art.

Embodiments consistent with the present invention also provide a method of forming a copper metal line, which can reduce a manufacturing cost by using related art processes and equipments.

Embodiments consistent with the present invention also provide a method that prevents a seed layer from being oxidized when forming a copper metal line by electroplating.

Embodiments consistent with the present invention further provide a semiconductor device including a copper metal line, which can be manufactured at a low cost using conventional processes and equipment, and has an improved performance by using a seed layer that does not oxidize during electroplating.

Consistent with embodiments of the present invention, a semiconductor device includes a substrate having a bottom metal line formed therein; a nitride layer and an oxide layer having a trench and a via hole, the via hole exposing the bottom metal line; a barrier metal layer formed inside the trench and the via hole; a seed layer formed on the barrier metal layer inside the trench and the via hole; and a copper line formed on the seed layer inside the trench and the via hole.

Consistent with embodiments of the present invention, a method for forming a copper metal line includes forming a bottom metal line on a substrate; sequentially forming a nitride layer and an oxide layer on the substrate; selectively removing the oxide layer to form a via hole, the via hole exposing a portion of the nitride layer; forming a photosensitive layer inside the via hole; selectively removing the oxide layer to form a trench over the via hole; removing the portion of the nitride layer exposed through the via hole; forming a barrier metal layer on sidewalls and a bottom of the via hole and the trench; and forming a seed layer on the barrier metal layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 to 5 are views illustrating a method of forming a copper metal line consistent with a first embodiment of the present invention; and

FIG. 6 is a view of a structure of a copper metal line consistent with a second embodiment of the present invention.

### DETAILED DESCRIPTION

Reference will now be made in detail to embodiments consistent with the present invention, examples of which are illustrated in the accompanying drawings. Wherever possible, the same reference numbers will be used throughout the drawings to refer to the same or like parts.

### First Embodiment

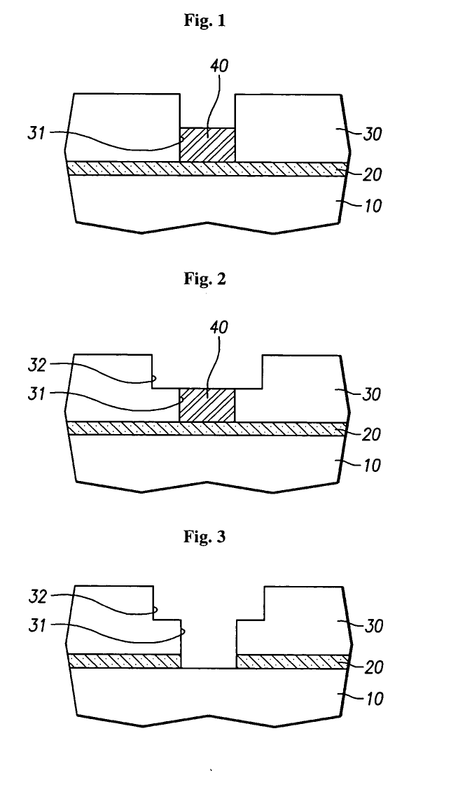

FIGS. 1 to 5 are views illustrating a method of forming a copper metal line consistent with a first embodiment of the present invention.

Referring to FIG. 1, an insulation layer including a nitride layer 20 and an oxide layer 30 is deposited on a substrate 10. The substrate 10 may include a bottom metal line formed therein. Next, a via hole 31 is formed in the oxide layer 30 using a conventional photolithography process. The nitride layer 20 formed below the oxide layer 30 is used as an etch stop layer during the formation of the via hole 31.

Next, a photosensitive layer (not shown) is formed on the entire surface of the oxide layer 30, and is patterned to form a photosensitive pattern 40 exclusively inside the via hole 31. As illustrated in FIG. 2, a trench 32 is formed on the oxide layer 30 using a photolithography process with the photosensitive pattern 40 formed inside the via hole 31 as an etch stop layer. As illustrated in FIG. 3, the photosensitive pattern 40 is removed, and the nitride layer 20 exposed in the via hole 31 is removed.

Referring to FIG. 4, a barrier metal layer 50 is formed along the sidewalls and the bottom of the via hole 31 and the trench 32. The barrier metal layer 50 may be formed of a Ti-based metal layer. For example, the barrier metal layer 50 may comprise one of a Ti layer, a TiN layer, and a composition of a Ti layer and a TiN layer. In the first embodiment, the Ti layer may be formed by CVD using a 2250 W DC power and an Ar gas at a flow rate of 58 sccm, and may have a thickness of about 150 to 600 Å. The TiN layer may be formed by CVD using a 8000 W DC power, an Ar gas at a flow rate of 20 sccm, and a N₂ gas at a flow rate of 75 sccm, and may have a thickness of about 150 to 600 Å. The Ti-based barrier metal layer 50 has a high resistance, and therefore is not used as a diffusion barrier for a copper metal line. Instead, the Ti-based barrier metal layer 50 is used as the diffusion barrier for an aluminum see layer to be formed thereon.

Next, a seed layer 60 is formed on the barrier metal layer 50 for copper plating. The seed layer 60 may comprise aluminum. The aluminum seed layer 60 may increase a metal line resistance. However, because a thickness of the aluminum seed layer 60 is very small compared to the thickness of the entire meal line, influence of the aluminum seed layer 60 on the resistance of the metal line is very small.

Consistent with the first embodiment of the present invention, the aluminum seed layer 60 may be formed by CVD using a 10600 W DC power, and an Ar gas at a flow rate of 35 sccm. The aluminum seed layer 60 may have a thickness of about 300 to 1200 Å. As an alternative to aluminum, materials such as Ru, Cu, Au, Ag, W, Ir, and Rh may also be used as the seed layer 60.

Referring to FIG. 5, copper is deposited on the seed layer 60 and in the via hole 31 and the trench 32 using an electroplating method, and then polished using a CMP process until the oxide layer 30 is exposed to form a copper metal line 70. Conventional processes may follow to complete a semiconductor device.

### Second Embodiment

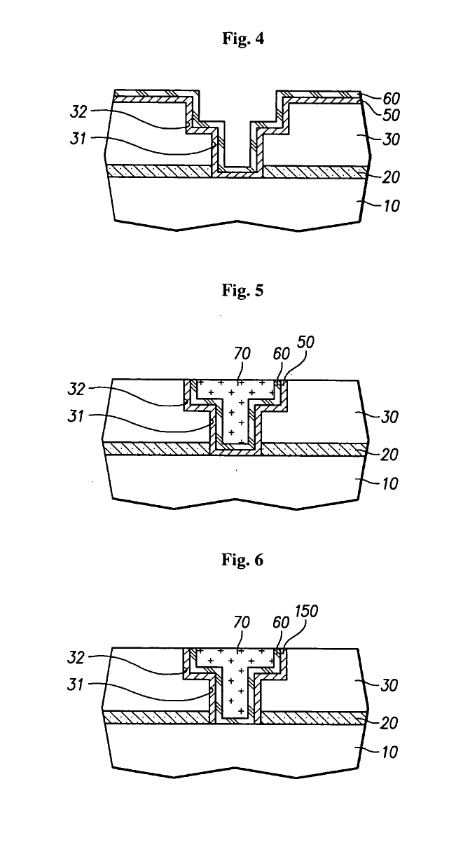

FIG. 6 is a view of a structure of a copper metal line consistent with a second embodiment of the present invention. Instead of forming the barrier metal layer 50 along the sidewalls and the bottom of the via hole 31 and the trench 32, as illustrated in FIG. 4, consistent with the second embodiment of the present invention, a barrier metal layer 150 is formed along the sidewalls and the bottom of the via hole 31 and the trench 32, but a portion of the barrier metal layer 150 on the bottom of the via hole 31 is removed by etching to reduce a contact resistance.

To form the structure shown in FIG. 6 consistent with the second embodiment of the present invention, the same processes as illustrated in FIGS. 1 to 3 are first performed. Then, the barrier metal layer 150 is formed along the sidewalls and the bottom of the trench 32 and the via hole 31. The barrier metal layer 150 may be formed of a Ti-based metal layer. For example, the barrier metal layer 150 may comprise one of a Ti layer, a TiN layer, and a composition of a Ti layer and a TiN layer. Consistent with the second embodiment of the present invention, the Ti layer may be formed by CVD using a 2250 W DC power and an Ar gas at a flow rate of 58 sccm, and may have a thickness of about 150 to 600 Å. The TiN layer may be formed by CVD using a 8000 W DC power, an Ar gas at a flow rate of 20 sccm, and a N₂ gas at a flow rate of 75 sccm, and may have a thickness of about 150 to 600 Å. The Ti-based barrier metal layer 50 has a high resistance, and therefore is not used as a diffusion barrier for a copper metal line. Instead, the Ti-based barrier metal layer 50 is used as the diffusion barrier for an aluminum see layer to be formed thereon.

The portion of the barrier metal layer 150 formed on the bottom of the via hole 31 is then etched by an etching process to expose a bottom metal line layer (not shown) in the substrate 10.

Next, a seed layer 60 is formed on the barrier metal layer 150 for copper plating. The seed layer 60 may comprise aluminum. The seed layer 60 increases a metal line resistance. However, because a thickness of the seed layer 60 is very small compared to the thickness of the entire metal line, influence of the aluminum seed layer 60 is very small.

Consistent with the second embodiment of the present invention, the aluminum seed layer 60 may be formed by CVD using a 10600 W DC power, and an Ar gas at a flow rate of 35 sccm. The aluminum seed layer 60 may have a thickness of about 300 to 1200 Å. As an alternative to aluminum, materials such as Ru, Cu, Au, Ag, W, Ir, and Rh may also be used as the seed layer 60.

Copper is filled into the via hole 31 and the trench 32 and on the seed layer 60 using an electroplating method, and is then polished using a CMP process until the oxide layer 30 is exposed to form a copper metal line 70. Conventional processes may follow to complete a semiconductor device.

Consistent with the second embodiment, because the seed layer 60 directly contacts a bottom line layer, contact resistance is lower than that consistent with the first embodiment.

Consistent with embodiments of the present invention, when aluminum is used as an electroplating seed layer of a copper metal line, a Ti-based metal target may be used, thereby reducing a cost of manufacturing semiconductor devices. In addition, aluminum does not easily oxidize when exposed to air as compared to copper. Therefore, performance of a semiconductor device including a metal line formed by methods consistent with the present invention is improved.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A semiconductor device, comprising:
a substrate having a bottom metal line formed therein;
a nitride layer and an oxide layer having a trench and a via hole, the via hole exposing the bottom metal line;
a barrier metal layer formed inside the trench and the via hole;
a seed layer formed on the barrier metal layer inside the trench and the via hole; and
a copper line formed on the seed layer inside the trench and the via hole.

2. The semiconductor device of claim 1, wherein the barrier metal layer comprises one of Ti, TiN, and a composition of a Ti layer and a TiN layer.

3. The semiconductor device of claim 1, wherein the barrier metal layer comprises one of a Ti layer having a thickness of about 150 to 600 Å, a TiN layer having a thickness about 150 to 600 Å, and a composition of a Ti layer and a TiN layer each having a thickness of about 150 to 600 Å.

4. The semiconductor device of claim 1, wherein the seed layer comprises a material selected from a group consisting of Al, Ru, Cu, Au, Ag, W, Ir, and Rh.

5. The semiconductor device of claim 4, wherein the seed layer has a thickness of about 300 to 1200 Å.

6. The semiconductor device of claim 1, wherein the bottom metal line electrically contacts the copper line through the barrier metal layer and the seed layer.

7. The semiconductor device of claim 1, wherein the seed layer directly connects the bottom metal line to the copper line.

8. A method for forming a copper metal line, comprising:
forming a bottom metal line on a substrate;
sequentially forming a nitride layer and an oxide layer on the substrate;
selectively removing the oxide layer to form a via hole, the via hole exposing a portion of the nitride layer;
forming a photosensitive layer inside the via hole;
selectively removing the oxide layer to form a trench over the via hole;
removing the portion of the nitride layer exposed through the via hole;
forming a barrier metal layer on sidewalls and a bottom of the via hole and the trench; and
forming a seed layer on the barrier metal layer.

9. The method of claim 8, further comprising, after the forming of the seed layer:
forming a copper layer using an electroplating method; and
polishing the copper layer to form a copper line.

10. The method of claim 8, further comprising removing the photosensitive layer inside the via hole.

11. The method of claim 8, wherein forming the barrier metal layer comprises forming one of a Ti layer, a TiN layer, and a composition of a Ti layer and a TiN layer.

12. The method of claim 8, wherein forming the barrier metal layer comprises forming one of a Ti layer having a thickness of about 150 to 600 Å, a TiN layer having a thickness of about 150 to 600 Å, and a composition of a Ti layer and a TiN layer each having a thickness of about 150 to 600 Å.

13. The method of claim 8, wherein forming the barrier metal layer comprises forming a Ti layer using CVD with a 2250 W DC power and an Ar gas at a flow rate of about 58 sccm.

14. The method of claim 8, wherein forming the barrier metal layer comprises forming a TiN layer using CVD with a 8000 W DC power, an Ar gas at a flow rate of about 20 sccm, and a N₂ gas at a flow rate of about 75 sccm.

15. The method of claim 8, wherein forming the seed layer comprises forming the seed layer with a material selected from a group consisting of Al, Ru, Cu, Au, Ag, W, Ir, and Rh.

16. The method of claim 8, wherein forming the seed layer comprises forming an aluminum layer using CVD with a 10600 W DC power, and an Ar gas at a flow rate of about 35 sccm.

17. The method of claim 8, wherein forming the seed layer comprises forming an aluminum layer having a thickness of about 300 to 1200 Å

18. The method of claim 8, further comprising, after the forming of the barrier metal layer, removing a portion of the barrier metal layer formed on the bottom of the via hole.
